(19) United States
(12) Patent Application Publication
(10) Pub. No.: US 2026/0113931 A1
(43) Pub. Date: Apr. 23, 2026

(54) One-Time Programmable Memory with Vertically Integrated Selector

(71) Applicant: Donghyuk Ju, Seattle, WA (US)

(72) Inventor: Donghyuk Ju, Seattle, WA (US)

(21) Appl. No.: 18/920,890

(22) Filed: Oct. 19, 2024

(51) Int. Cl. H10B 20/25; G11C 17/16; G11C 17/18

(52) U.S. Cl. CPC H10B 20/25; G11C 17/16; G11C 17/18

(57) ABSTRACT

An antifuse one-time programmable memory bit cell comprises a metal-oxide-semiconductor (MOS) gate electrode and diffusions formed in an isolated well. The surface of the isolated well under the MOS gate electrode is the drain, the bottom portion of the isolated well is the source of a vertical junction field-effect transistor (JFET), and the diffusions are the JFET gate. The MOS gate electrode is the word line, and the diffusions are the bit line. The vertical JFET is turned on or off by a voltage applied to the JFET gate and functions as a bit cell selector device.

### CROSS-REFERENCE TO RELATED APPLICATIONS

N/A

### FIELD OF THE INVENTION

The present invention generally relates to semiconductor memory, specifically to antifuse one-time programmable memory.

### BACKGROUND OF THE INVENTION

An antifuse, unlike a fuse that blocks current flow when disturbed, conducts little current in an undisturbed or unprogrammed state and becomes electrically conductive when disturbed or programmed. The unprogrammed and programmed states of an antifuse can be used to store digital data “0” and “1”, i.e., a memory device can be built with an antifuse.

A common method of making an antifuse in a semiconductor chip uses a thin dielectric layer sandwiched between two conducting materials or electrodes. In an unprogrammed antifuse-its natural state-the dielectric layer blocks current flow between the two electrodes. To program an antifuse, a high voltage is applied between the two electrodes to cause the dielectric to break down. After the dielectric breakdown, the antifuse can conduct current, i.e., the antifuse is programmed.

Programming of an antifuse permanently changes its electrical properties. Once programmed, an antifuse cannot revert to an unprogrammed state. Therefore, a memory device fabricated with an antifuse can be programmed only once, i.e., a one-time programmable (OTP) memory. Antifuse OTP memory retains data after power is turned off, so it belongs to a group of semiconductor memories classified as non-volatile memory (NVM).

Antifuse OTP memory is generally used as an embedded memory in integrated circuit (IC) chips to store program codes and security codes, trim analog circuits, and repair dynamic random-access memory (DRAM), to name just a few. It is an integral part of digital, analog, and mixed-signal integrated circuits and is used extensively in consumer, industrial, automotive, and internet-of-things (IoT) applications.

In ICs fabricated with a complementary metal-oxide-semiconductor (CMOS) process—the mainstream IC manufacturing process today-a metal-oxide-semiconductor (MOS) capacitor is commonly used as an antifuse to build OTP memory. A memory bit cell can be constructed by connecting a selector transistor in series with an MOS capacitor, resulting in a conventional one-transistor one-capacitor (1T1C) bit cell.

A schematic drawing of an exemplary antifuse 1T1C bit cell is shown in FIG. 1, a prior art. The N-channel MOS field-effect transistor (MOSFET) inside circle 101 is a selector transistor and the MOS capacitor inside circle 102 is antifuse. The gates of the MOSFET and MOS capacitor are tied together and act as the word line (WL), and the source of the MOSFET is the bit line (BL). FIG. 1 illustrates that the MOSFET is a thick gate dielectric device used, for example, for input/output (I/O) circuits and the MOS capacitor is a thin gate dielectric device used for core circuits in logic ICs.

FIG. 2 is a cross-sectional drawing of FIG. 1 when fabricated with an exemplary CMOS process. Inside circles 201 and 202 of FIG. 2 are a selector N-channel MOSFET and an antifuse MOS capacitor, respectively. FIG. 2 shows details of each part of the MOSFET and MOS capacitor, such as N+ gate polysilicon, N+ source/drain diffusions, a high-voltage lightly doped drain (N_{hvldd}), a low-voltage lightly doped drain (N_{lvldd}), P-type well, P-type substrate and shallow trench isolation (STI), all of which are formed by a standard CMOS process. The arrow in FIG. 2 indicates the direction of the current path in a selected programmed cell. Note that the current flows horizontally from the MOS capacitor through the selector MOSFET to the bit line. An advantage of the 1T1C bit cell is that its structure conforms to a standard CMOS process, so there is no need to add extra processing steps or change manufacturing procedures.

One shortcoming of the 1T1C bit cell is that read current variation can be large across a memory array as the amount of read current depends on the location of gate dielectric breakdown in the MOS capacitor channel. Another shortcoming is that the selector MOSFET occupies a large portion of a bit cell area and can be a roadblock to achieving a high-density memory and continued scaling.

Several attempts have been made to address the shortcomings of the 1T1C bit cell. Realizing that the diode produced after a bit cell is programmed can be used as a selector device, H. Luan, et al. disclosed a compact bit cell without a separate selector transistor in U.S. Pat. No. 8,330,189. FIG. 3A and FIG. 3B are the cross-sectional drawings therein. The bit cell, however, requires additional processing steps increasing the manufacturing cost. The bit cell also has an inherent cell current variability across a memory array. Another attempt to address the shortcomings of 1T1C bit cell is disclosed in U.S. Pat. No. 9,142,316 by Y. Liu, et al., where N-type well in a standard CMOS process is used as bit line diffusion and selector transistor is eliminated from the bit cell. The bit cell does not require additional processing steps and conforms to standard CMOS processes. However, since the N-type well junction is deep, the bit cell requires a large spacing between adjacent bit lines and as a result, a compact bit cell is difficult to attain. U.S. Pat. No. 11,152,382 by D. Ju overcomes the shortcomings of the aforementioned prior arts with a shallow continuous bit line diffusion formed by lateral diffusion of dopants from the high-voltage lightly doped drain (N_{hvldd}) as shown in FIG. 4. Though the bit cell is compact and does not require additional processing steps, it does not conform to standard CMOS processes. Note that in the bit cell of FIG. 4, the doping type of gate electrode is opposite to that of the source and drain, whereas, in a standard CMOS process, the doping types of gate electrode and source/drain of a MOSFET are the same. Also note that in FIG. 4 N_{hvldd} is used in conjunction with thin gate dielectric, whereas in a standard CMOS process, N_{lvldd} is used with thin gate dielectric. The structural differences in FIG. 4 from a standard CMOS process, though not requiring additional processing steps, require modifications to standard CMOS manufacturing procedures such as mask layer generation algorithms from layout drawings. U.S. Pat. No. 11,152,382 also discloses a bit cell operation wherein the current flows vertically from the word line through a junction field-effect transistor (JFET) as shown in FIG. 5. The bit cell structure of FIG. 5, similar to FIG. 4, does not conform to standard CMOS processes and manufacturing procedures.

For today's highly complex IC manufacturing processes, it is much desired for a new invention to conform to standard CMOS processes and manufacturing procedures thereby eliminating the need for extra effort by semiconductor foundry manufacturers and the source of potential errors. This is particularly true for a new invention targeted at embedded applications as it will be designed into an IC that uses a standard CMOS process. Therefore, it is desired to have antifuse OTP memory that features a compact bit cell and high performance and also conforms to standard CMOS processes and manufacturing procedures.

### BRIEF SUMMARY OF THE INVENTION

An antifuse OTP memory bit cell comprises a MOS capacitor formed with a gate electrode, a thin gate dielectric, and source/drain diffusions formed in an active area inside an isolated well. The gate electrode is the word line, and the source/drain diffusions formed on the side of the gate electrode are the bit line. Current flows vertically during a program or read operation between the word line and the bottom portion of the well. The bit line voltage controls the current flowing through a selector JFET vertically integrated into the MOS capacitor.

### BRIEF DESCRIPTION OF THE DRAWINGS

FIG. 1 is a schematic drawing of the one-transistor one-capacitor (1T1C) antifuse OTP memory bit cell found in the prior art.

FIG. 2 is a cross-sectional drawing of the 1T1C bit cell of FIG. 1, a prior art.

FIG. 3A and FIG. 3B are cross-sectional drawings of the antifuse OTP memory bit cell disclosed in U.S. Pat. No. 8,330,189, a prior art.

FIG. 4 is a cross-sectional drawing of the antifuse OTP memory bit cell disclosed in U.S. Pat. No. 11,152,382, a prior art.

FIG. 5 is another cross-sectional drawing of the antifuse OTP memory bit cell disclosed in U.S. Pat. No. 11,152,382, a prior art.

FIG. 6 is an exemplary structural cross-section of an antifuse OTP memory bit cell according to one embodiment of the present invention.

FIG. 7A is a cross-sectional drawing of a selected bit cell for a program mode according to the embodiment of the present invention shown in FIG. 6.

FIG. 7B is a cross-sectional drawing of an unselected unprogrammed bit cell for a program mode according to the embodiment of the present invention shown in FIG. 6.

FIG. 7C is a cross-sectional drawing of an unselected programmed bit cell for a program mode according to the embodiment of the present invention shown in FIG. 6.

FIG. 8A and FIG. 8B are cross-sectional drawings of programmed bit cells for a read mode for selected and unselected bit cells respectively, according to the embodiment of the present invention shown in FIG. 6.

FIG. 9A and FIG. 9B are schematic representations of unprogrammed and programmed bit cells, respectively, of the embodiment of the present invention shown in FIG. 6.

FIG. 10 is an exemplary cross-sectional drawing of an antifuse OTP memory bit cell according to another embodiment of the present invention.

FIG. 11 is an exemplary cross-sectional drawing of an antifuse OTP memory bit cell according to yet another embodiment of the present invention wherein the bit cell is realized in an isolated P-type well inside an N-type well in a P-type substrate.

FIG. 12 is a three-dimensional view of an antifuse OTP memory bit cell according to yet another embodiment of the present invention wherein the bit cell is formed in a silicon fin using a 3-dimensional MOSFET CMOS process.

FIG. 13 is a top view of an exemplary layout of a 3×3 memory array designed with the embodiment of the present invention shown in FIG. 6.

FIG. 14A and FIG. 14B are cross-sectional views of FIG. 13 along the bit line direction and the word line direction, respectively.

FIG. 15 is an exemplary schematic circuit and bias condition for a program mode of the 3×3 memory array layout shown in FIG. 13.

FIG. 16 is an exemplary schematic circuit and bias condition for a read mode of the 3×3 memory array layout shown in FIG. 13.

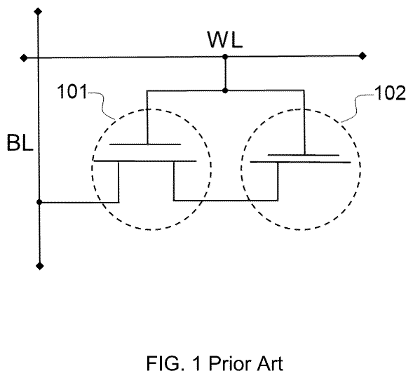

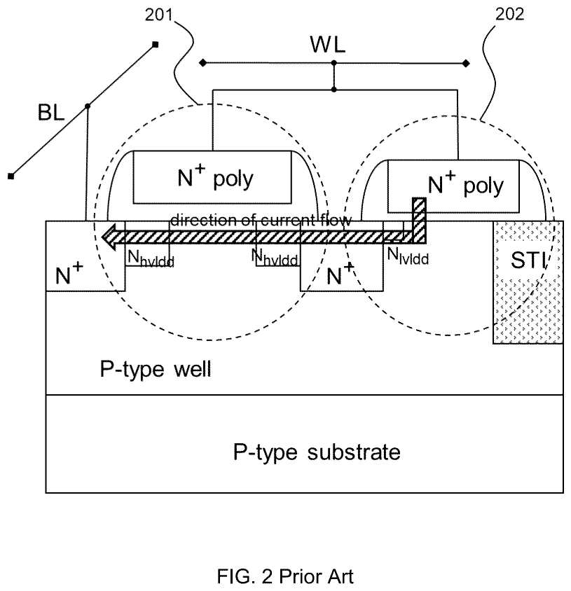

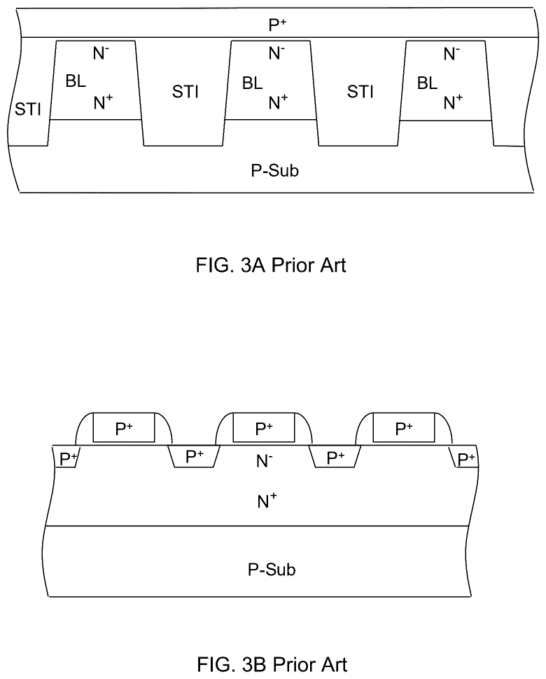

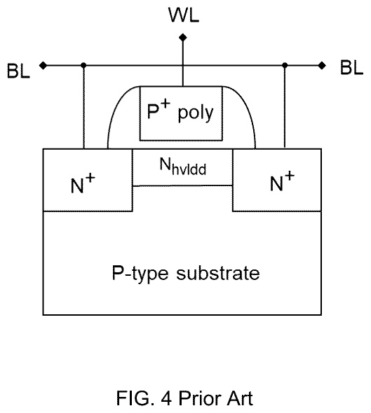

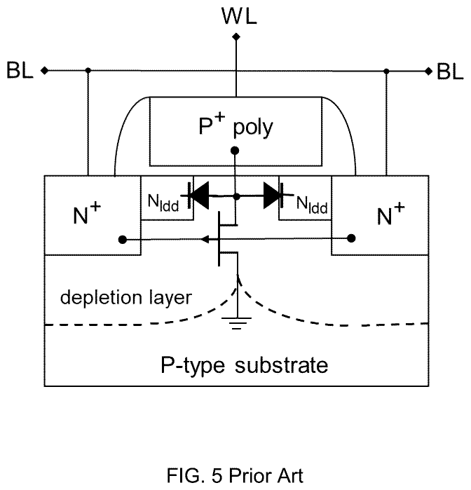

### DETAILED DESCRIPTION OF THE INVENTION

The present invention employs a junction field-effect transistor (JFET) as a bit cell selector device. The JFET is vertically integrated with an antifuse MOS capacitor. As a result, the bit cell is much smaller than the traditional 1T1C bit cell where the selector transistor is laid out laterally to the antifuse MOS capacitor. Furthermore, the present invention conforms to standard CMOS processes and thus does not need additional processing steps or modifications to CMOS manufacturing procedures.

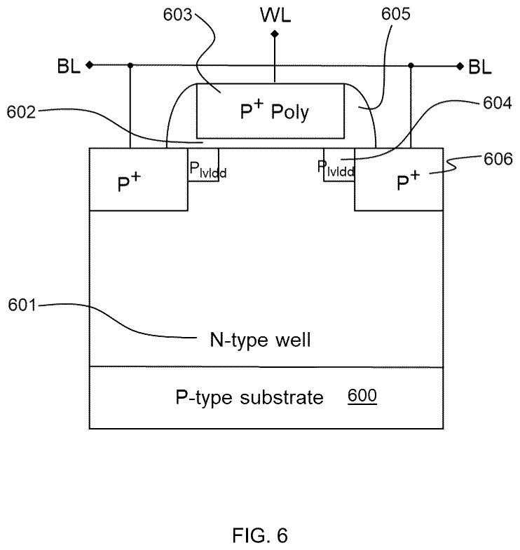

FIG. 6 is a cross-sectional view of an antifuse OTP memory bit cell according to one embodiment of the present invention. The fabrication of the present invention follows a standard CMOS process, details of which are described below. Substrate 600 is a P-type non-epitaxial silicon wafer, wherein the substrate doping concentration is 2.0×10¹⁵/cm³˜2.0×10¹⁶/cm³, a doping concentration commonly found in non-epitaxial silicon wafers. An N-type well 601 is formed in the P-type substrate by an ion implantation process that counter-dopes the substrate and converts the region into N-type silicon. Active areas are defined when shallow trench isolation (STI)—not seen along the cut direction of FIG. 6—is formed. STI is typically 0.25 micrometers (μm) to 0.35 μm deep and filled with silicon dioxide. A thin gate dielectric 602 is deposited in the active area. After undoped polysilicon 603 is deposited and patterned, ion implantation is performed, creating a P-channel low-voltage lightly doped drain (P_{lvldd}) 604, also known as source/drain extension. Gate sidewall spacer 605 is subsequently formed, followed by an ion implantation to create P⁺ source/drain diffusions 606 and at the same time to dope the gate polysilicon into P⁺. FIG. 6 is structurally the same as a P-channel MOSFET found in a standard CMOS process ensuring complete conformance with standard CMOS processes. The present invention differs from the standard P-channel MOSFET in how each part of FIG. 6 is connected, and the way voltages are applied. Note that in FIG. 6 the two source/drain diffusions are connected forming a bit line whereas in a P-channel MOSFET, the source and drain are separate terminals. As described in the next paragraph, the voltage biasing scheme for FIG. 6 is also different from that of a P-channel MOSFET. These differences transform the structure depicted in FIG. 6, while it is structurally the same as a P-channel MOSFET, into the antifuse memory bit cell of the present invention wherein a JFET is vertically integrated with an antifuse MOS capacitor and acts as a bit cell selector.

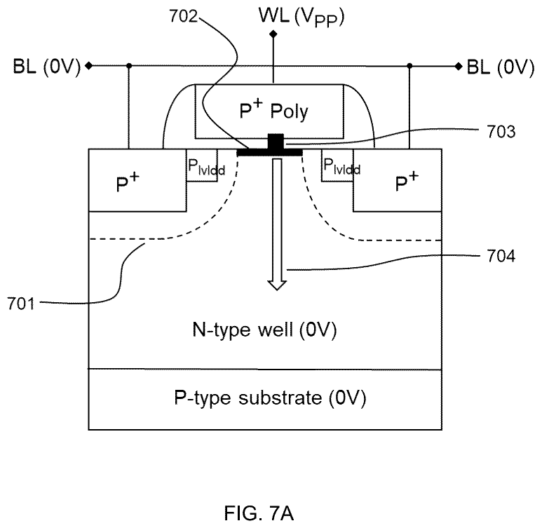

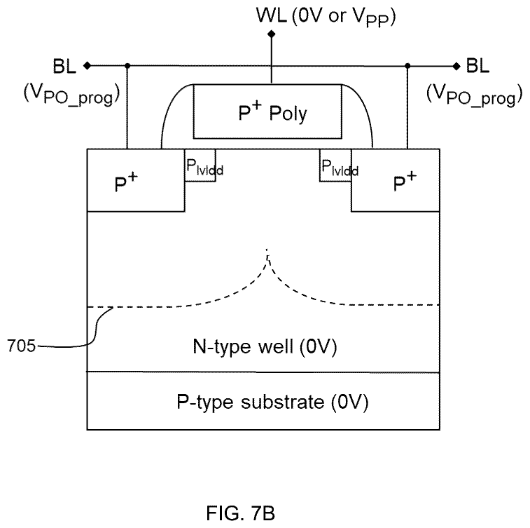

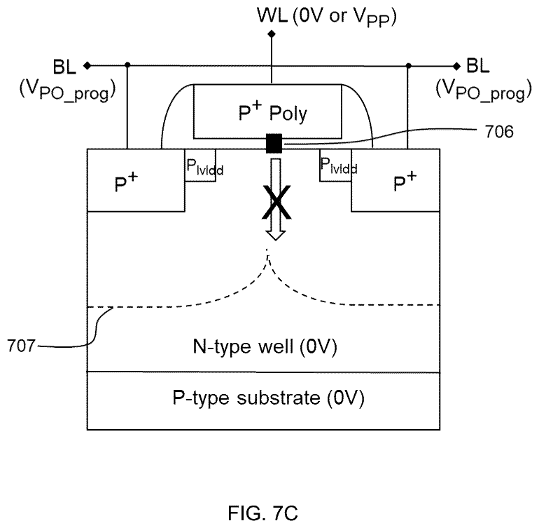

FIG. 7A is a cross-sectional drawing of a selected bit cell during a program mode according to the embodiment of the present invention shown in FIG. 6. A positive programming voltage V_{PP} is applied to the gate (word line) and the P⁺/P_{lvldd} diffusions (bit line) are biased to 0 volt. An N-type well for P-channel MOSFETs is biased to a positive voltage V_{dd}. In contrast, the N-type well in FIG. 7A is biased to 0 volt and so is the P-type substrate. The broken line 701 indicates the depletion region boundary between the P⁺/P_{lvldd} diffusions and the N-type well. Since both P⁺/P_{lvldd} diffusions and the N-type well are biased to 0 volt, the depletion region is narrow and there is undepleted silicon in the channel between the two P⁺/P_{lvldd} diffusions. The positive programming voltage V_{PP} applied to the gate causes electrons to accumulate at the surface of the N-type well forming an accumulation layer 702. A weak spot in the gate dielectric breaks down and current flows from the gate through a forward-biased P⁺/N-type well diode created at the ruptured spot 703, then through the N-type well in between the two P⁺/P_{lvldd} diffusions downward, and flows to the N-type well ground terminal, as indicated by the arrow 704. The width of the depletion region can be modulated by varying the bit line voltage, which modulates the amount of current flowing through the N-type well between the two P⁺/P_{lvldd} diffusions. Therefore, the structure functions as a depletion-mode N-channel JFET wherein the surface of the N-type well is the drain, the lower portion of the N-type well outside the depletion region is the source, and P⁺/P_{lvldd} diffusions are the JFET gate.

JFETs can be turned off by applying a negative voltage to the P⁺/P_{lvldd} diffusions, thus enabling them to deselect bit cells. FIG. 7B is a cross-sectional drawing of an unselected unprogrammed bit cell during a program mode according to the embodiment of the present invention shown in FIG. 6. The word line voltage of an unselected bit cell is either 0 volt or V_{PP}. The bit line voltage V_{PO_prog} applied to the P⁺/P_{lvldd} diffusions is the JFET pinch-off voltage for program mode. V_{PO_prog} is negative and causes the N-type well between the two P⁺/P_{lvldd} diffusions to deplete fully of electrons as indicated by the depletion region boundary 705. Under such a condition, the electron accumulation layer is not formed at the surface of the N-type well and the unselected bit cell is not programmed.

FIG. 7C is a cross-sectional drawing of an unselected programmed bit cell during a program mode according to the embodiment of the present invention shown in FIG. 6. The bias condition of FIG. 7C is the same as that of FIG. 7B. FIG. 7C shows spot 706 where the gate dielectric had ruptured in a prior programming cycle. Though a PN diode exists at spot 706 between the gate electrode and N-type well surface, current flow from the gate electrode to the N-type well ground is prevented because the N-type well between the two P⁺/P_{lvldd} diffusions is fully depleted of electrons as indicated by the depletion region boundary 707, i.e., the vertical JFET off.

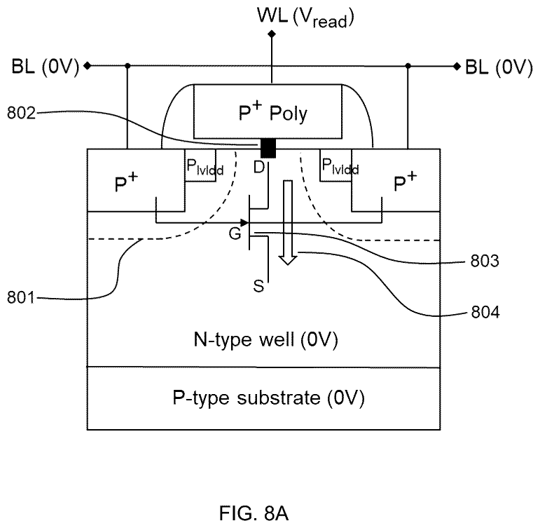

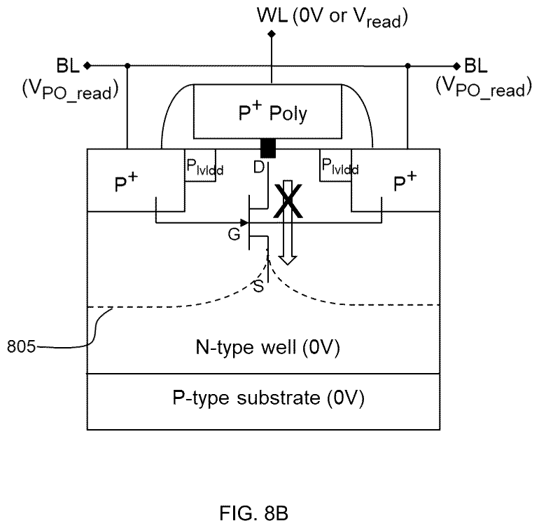

FIG. 8A is a cross-sectional drawing of a selected programmed bit cell during a read mode according to the embodiment of the present invention shown in FIG. 6. A positive read voltage V_{read} is applied to the gate and the P⁺/P_{lvldd} diffusions are biased to 0 volt. The N-type well is biased to 0 volt and so is the P-type substrate. The broken line 801 indicates the depletion region boundary between the P⁺/P_{lvldd} diffusions and the N-type well. Since both P⁺/P_{lvldd} diffusions and the N-type well are biased to 0 volt, the depletion region is narrow and there is undepleted silicon in the JFET channel between the two P⁺/P_{lvldd} diffusions. A PN diode exists at 802 where the gate dielectric ruptured with the gate electrode as an anode and the surface of the N-type well as a cathode. With 0 volt applied to the P⁺/P_{lvldd} diffusions, the vertical JFET 803 is on, and current flows from the gate electrode through the diode, through the JFET 803, and to N-type well ground as arrow 804 indicates.

FIG. 8B is a cross-sectional drawing of an unselected programmed bit cell during a read mode according to the embodiment of the present invention shown in FIG. 6. The word line voltage of an unselected bit cell is either 0 volt or V_{read}. The bit line voltage V_{PO_read}, applied to the P⁺/P_{lvldd} diffusions is the JFET pinch-off voltage for read mode. V_{PO_read} is negative and causes the N-type well between the two P⁺/P_{lvldd} diffusions, i.e., the JFET channel, fully depleted as the depletion region boundary 805 indicates. Under such a condition, the JFET is off and current flow between the gate electrode through the diode and JFET is prevented. The value of V_{PO_read} can be the same as V_{PO_prog}, however, each can be optimized separately for optimal read and program operations.

It is to be noted that the full depletion of the vertical JFET channel is feasible with voltages practical for advanced CMOS IC chips. For example, the depletion region width of a one-sided PN junction with a background doping concentration of 5×10¹⁷/cm³ is 73 nm with a reverse bias voltage of 1 volt. This depletion region width is sufficient to deplete a JFET channel 100 nm wide as it is greater than half of the JFET channel width.

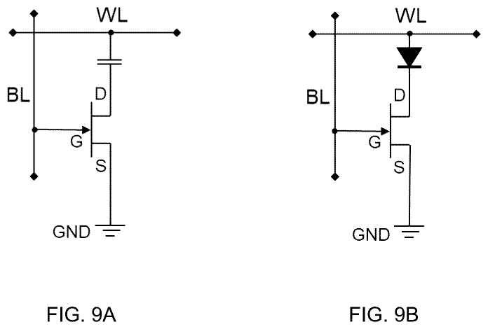

The exemplary embodiment of the present invention shown in FIG. 6 uses the P⁺/P_{lvldd} diffusions as the gate of the vertical JFET, of which the drain and source are located at the surface and the bottom portion of the N-type well, respectively, as illustrated in FIG. 8A and FIG. 8B. In an unprogrammed bit cell, the drain of the JFET is connected to the MOS capacitor above it as schematically illustrated in FIG. 9A. In a programmed cell, the drain of the JFET, which is also the cathode of the PN diode, is connected to the diode above it as schematically illustrated in FIG. 9B. The source of the JFET is at ground potential as shown in FIG. 9A and FIG. 9B.

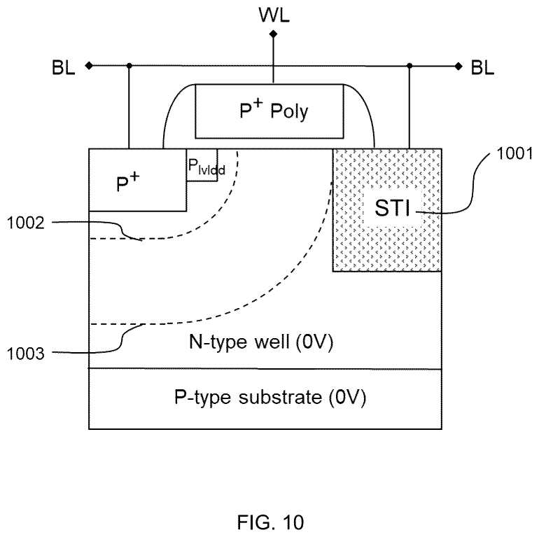

A bit cell of the present invention can also be realized by replacing one of the two P⁺/P_{lvldd} diffusions in FIG. 6 with an STI 1001 as shown in FIG. 10. Two broken lines 1002 and 1003 in FIG. 10 indicate depletion region boundaries when the vertical JFET is on and off, respectively. STI in FIG. 10 can be used as another design variable when determining the MOS capacitor length and operating voltages.

The bit cells presented above employ depletion-mode JFET; the JFET is on when the gate-to-source voltage is 0 volt. To turn the JFET off, the gate-to-source junction is reverse-biased to deplete the JFET channel fully. A bit cell of the present invention can also be built with an enhancement-mode JFET wherein the JFET is off, i.e., the JFET channel is fully depleted when the gate-to-source voltage is 0 volt. The depletion region shrinks as a forward bias applied to the gate-to-source junction increases, eventually opening up the JFET channel and enabling the current to flow through the JFET channel. Most logic CMOS processes offer MOSFETs with different threshold voltages (Vₜₕ), for example, low Vₜₕ, regular Vₜₕ, high Vₜₕ, and super-high Vₜₕ, etc., each of which is built on a different well doping concentration. By selecting a well-doping concentration optimal for the enhancement-mode JFET and using a gate-to-source forward voltage lower than a diode turn-on voltage, the JFET can conduct sufficient current through its channel while keeping the gate current low.

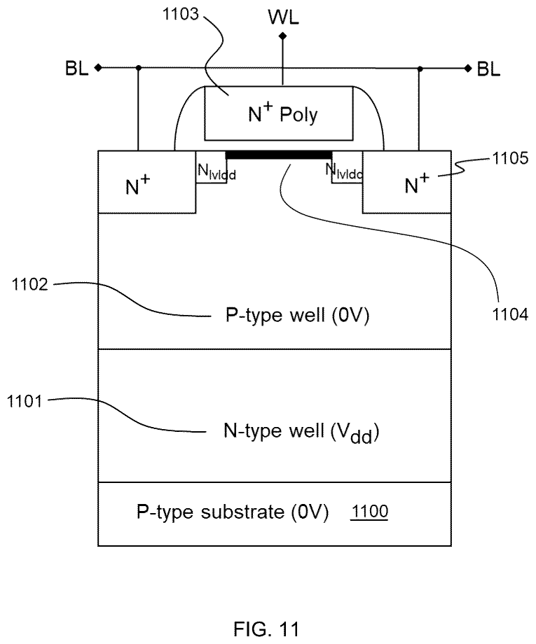

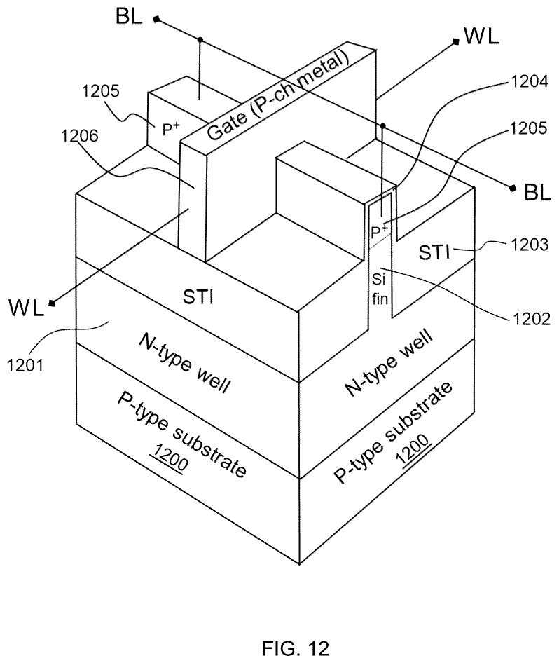

The embodiment of FIG. 6 was presented using an N-type well in a P-type substrate. The present invention can also be realized in an isolated P-type well, such as a P-type well inside a deep N-type well in a P-type substrate found in a triple-well CMOS process. FIG. 11 shows a cross-sectional drawing of an exemplary embodiment of the present invention realized with an isolated P-type well in a triple-well CMOS process. A P-type substrate 1100 is biased to 0 volt and a deep N-type well 1101 is biased to a positive voltage V_{dd}. An isolated P-type well 1102 is formed inside the deep N-type well 1101 and is biased to 0 volt. A negative programming voltage V_{PP} is applied to the gate electrode 1103 causing the surface 1104 of the P-type well to be accumulated with holes when the voltage at the source/drain diffusions 1105 is 0 volt. A positive voltage can also be used for V_{PP}, which forms a surface inversion layer 1104 with electrons. A positive V_{PP}, however, has a risk of gate dielectric breakdown occurring in the overlap area of the gate electrode with source/drain diffusions that will cause a short between the word line and bit line. For a negative V_{PP}, programming current flows from the bottom of the P-type well to the gate through the vertical P-channel JFET. In an unselected bit cell, a positive pinch-off voltage V_{PO_prog} applied to the source/drain diffusions 1105 prevents a hole accumulation layer from forming at the surface of the P-type well and thus keeps the bit cell from being programmed. Read operations of selected and unselected bit cells can be similarly explained.

Whereas the above presentations were made using a P-type substrate, the present invention can also be realized using an N-type substrate. Those of ordinary skill in the art will also recognize that the present invention can be realized with an epitaxial wafer as well as with a non-epitaxial wafer the above presentations were made.

It is to be noted that the horizontal and vertical dimensions of the various regions in the drawings of this disclosure, including the thicknesses of layers, depth and lateral reach of doped regions, depletion region widths, and relative lengths are not necessarily drawn to scale. In some cases, layer thicknesses, junction depths, lengths, and other dimensions are exaggerated to best illustrate the structural features and/or functional aspects of the present invention. It should also be mentioned that not all features employed by the standard CMOS process and known to those of ordinary skill in the art are described to avoid obfuscation of the key aspects of the disclosure.

Starting at about the 30 nm node of the CMOS process, metal replaces polysilicon as a gate electrode in conjunction with high dielectric constant (high-k) gate dielectric. At such process nodes, the gate depletion effect occurring in polysilicon gates becomes significant and impedes MOSFET scaling. The metal gate does not suffer from gate depletion and therefore using a metal gate is essential for MOSFET scaling at advanced CMOS nodes. In a dual metal gate CMOS process, two distinct metals with different work functions are used: one for the gate of N-channel MOSFET and the other for the gate of P-channel MOSFET to obtain respective threshold voltages. Therefore, the metal gates of N-channel MOSFET and P-channel MOSFET in a dual metal gate CMOS process play a similar role to N′ doped polysilicon gate and P⁺ doped polysilicon gate in silicon gate CMOS technology. Hence, the bit cell of the present invention can also be realized using a dual metal gate CMOS process. When fabricated with a metal gate CMOS process, the bit cell of the present invention is less susceptible to punch-through leakages between the word line and bit line than the one fabricated with a polysilicon gate CMOS process as the metal-to-semiconductor junction is a unipolar device.

The short-channel effects in two-dimensional (2D) MOSFETs are a barrier to continued scaling at advanced CMOS nodes. Below the 20 nm node, CMOS technology begins to migrate from the conventional 2D planar MOSFET to three-dimensional (3D) MOSFET. Fin-FET is an early version of the 3D MOSFET, and a more advanced version referred to as gate-all-around (GAA) MOSFET, also known as nanosheet MOSFET, will soon emerge as a production-worthy 3D CMOS device. In a Fin-FET CMOS process, MOSFETs are formed in a thin slice of semiconductor material protruding from the semiconductor substrate and the gate electrode wraps around the fin. As a result, the short-channel effects are mitigated, and the device scaling can continue. FIG. 12 is a 3D view of an exemplary bit cell of the present invention wherein the bit cell is formed using a Fin-FET structure and the gate electrode is metal. In FIG. 12, a silicon fin 1202 is shaped in an N-type well 1201 formed in the P-type substrate 1200. The silicon fin 1202 is isolated from the adjacent silicon fins by shallow trench isolation (STI) 1203. Gate electrode 1206 formed on a high-k gate dielectric 1204 is a P-channel metal and wraps around the silicon fin 1202. The gate is the word line and runs orthogonally to the silicon fin. P⁺ source/drain diffusions 1205 are formed in the silicon fin on both sides of the gate and are connected to a metal bit line (not shown) that runs parallel to the silicon fin.

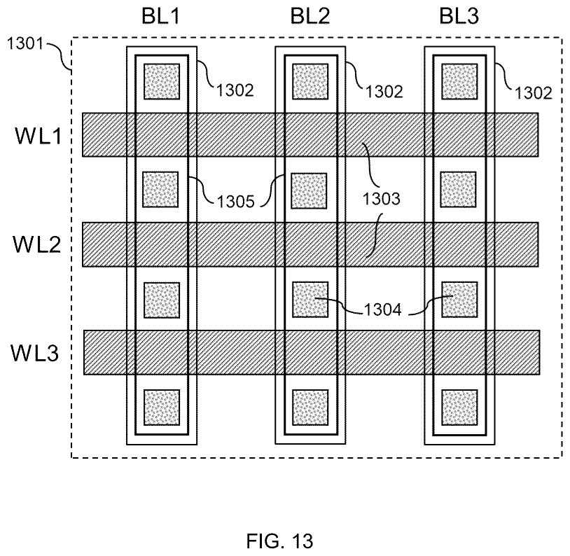

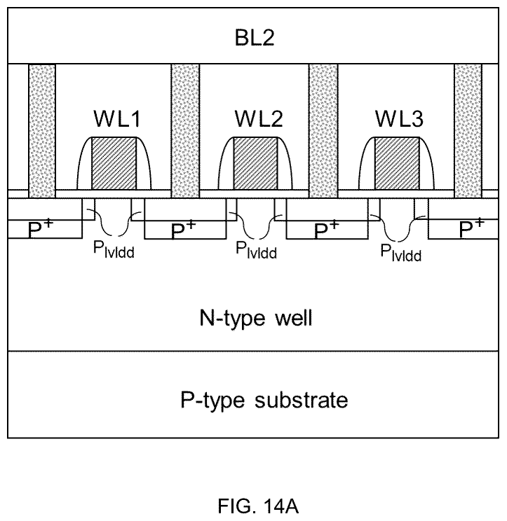

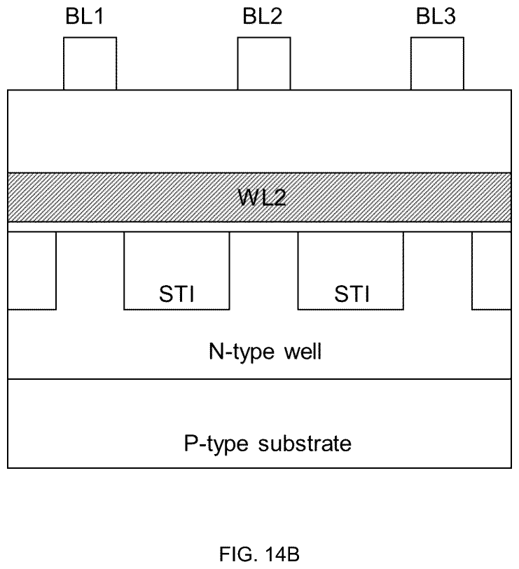

FIG. 13 is an exemplary layout of a 3×3 memory array using the embodiment of the present invention shown in FIG. 6. The outer boundary of the memory array 1301 is an N-type well implant pattern and indicates the memory array sits inside an N-type well. The pattern 1301 can also be used for P⁺ and P-channel lightly doped drain implants. Active area pattern 1302 is laid out in the vertical direction and the polysilicon gate 1303 is laid out in the horizontal direction but their orientations can be interchanged. The P⁺ diffusions in an active area are connected to the first level metal 1305 through contacts 1304 forming a bit line and the gate is a word line. The memory array layout is such that a bit cell exists at each intersection of a word line and a bit line. FIG. 14A and FIG. 14B are the cross-sectional drawings of the memory array layout of FIG. 13 in the bit line and the word line direction, respectively, with each part labeled as shown.

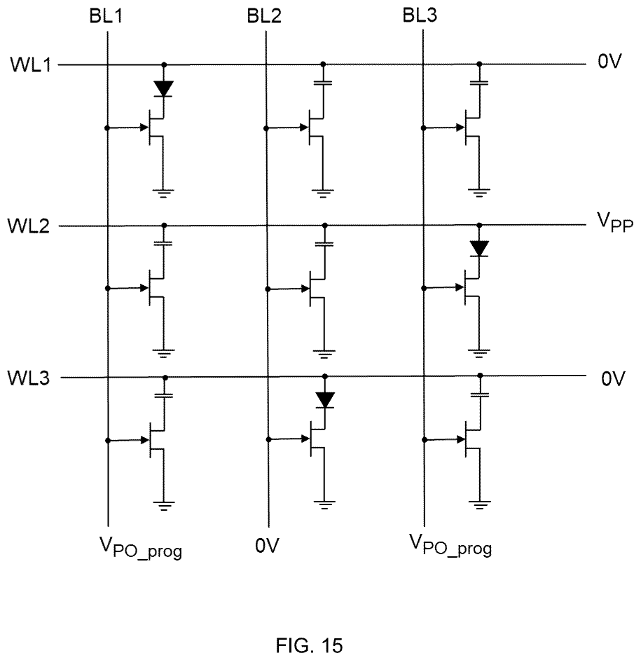

FIG. 15 is a schematic circuit of a 3×3 memory array with an exemplary bias condition for a program mode according to the embodiment of the present invention shown in FIG. 6. An unprogrammed bit cell is represented by a capacitor in series with a JFET. A bit cell programmed in a prior program mode is represented by a diode in series with a JFET. To program the bit cell found at WL2/BL2, a positive program voltage V_{PP} is applied to the selected word line WL2, and 0 volt is applied to the selected bit line BL2. The unselected word lines WL1 and WL3 are biased to 0 volt and the unselected bit lines BL1 and BL3 are biased to a negative voltage V_{PO_prog}. The value of V_{PP} depends on the thickness and strength of the gate dielectric. It ranges from about 3 volt for a CMOS node of 14 nm to about 6 volt for a 65 nm node. Under the given bias condition, the MOS capacitor channel, or the surface of the N-type well of the selected bit cell at WL2/BL2 is accumulated with electrons. After gate dielectric breakdown, programming current flows from the gate through the JFET channel to the ground terminal. In unselected unprogrammed bit cells such as those found at WL1/BL2 and WL3/BL3, the MOS capacitor channels are not accumulated with electrons, so those bit cells are not programmed. In unselected programmed bit cells located at WL1/BL1 and WL2/BL3, the vertical JFET is off allowing little current through it and thus does not disrupt the programming of the bit cell located at WL2/BL2.

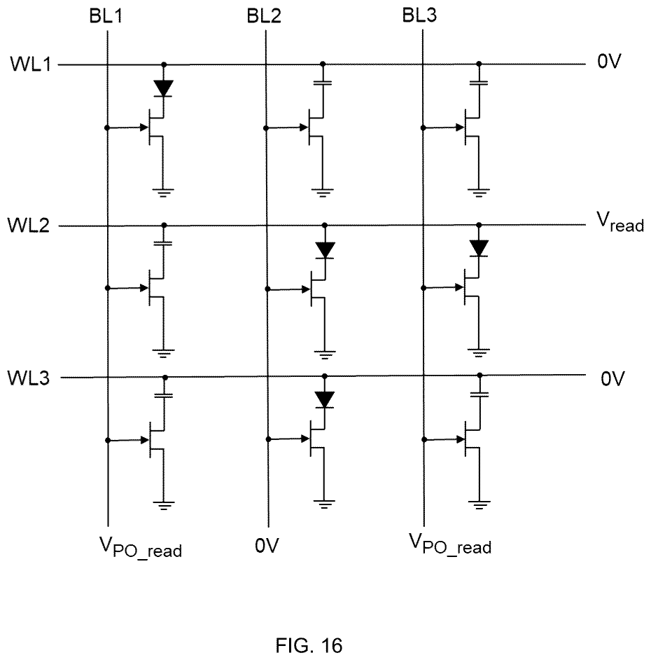

FIG. 16 is a schematic circuit of a 3×3 memory array with an exemplary bias condition for a read mode according to the embodiment of the present invention shown in FIG. 6. To read the bit cell found at WL2/BL2, a positive read voltage V_{read} is applied to the selected word line WL2, and 0 volt is applied to the selected bit line BL2. The unselected word lines WL1 and WL3 are biased to 0 volt and the unselected bit lines BL1 and BL3 are biased to a negative voltage V_{PO_read}. Since the diode turn-on voltage is about 0.7 volt for a silicon PN junction diode, and assuming a voltage drop of about one volt from the drain to the source of the JFET, a typical value of V_{read} can be about 1.7 volt suggesting that one of the logic IC supply voltages 1.8 volt can be used as V_{read}.

Under the given bias condition, the diode at WL2/BL2 is forward-biased, and current flows from WL2 to the source of the JFET, which is grounded. No current flows in unselected programmed bit cells because the diode has 0 volt across it or JFETs are off.

It should be understood that presentations have been made by way of example, and not limitation. It will be clear to people skilled in the relevant art that various changes in form and detail may be made therein without departing from the spirit and scope of the invention. Therefore, the scope of the invention should be decided not concerning the above description, but instead by reference to the appended claims, along with the full scope of equivalents to which such claims are entitled.

What is claimed is:

1. A semiconductor one-time programmable memory bit cell comprising:
an active area disposed in a well of a first conductivity type disposed in a semiconductor of a second conductivity type,
a gate dielectric layer disposed on said active area,
a gate electrode disposed on said gate dielectric and across a part of said active area,
diffusion regions of the second conductivity type disposed in said active area not covered by said gate electrode,
a metal connected to said diffusion regions of the second conductivity type through contact holes disposed on said diffusion regions, and
shallow trench isolation (STI) disposed in said well of the first conductivity type, wherein said gate electrode forms a rectifying junction with said well of the first conductivity type after a breakdown of the said gate dielectric, said diffusion regions of the second conductivity type act as a gate of a vertical junction field-effect transistor (JFET), the top and bottom portions of said well of the first conductivity type under said gate electrode act as the drain and source of said JFET, current after a gate dielectric breakdown flows vertically between the said gate electrode and the bottom portion of said well of the first conductivity type, said gate electrode is a word line, said metal is a bit line, a voltage applied to the bit line turns said JFET on or off thereby enabling said JFET to function as a bit cell selector device.

2. The memory bit cell of claim 1 wherein the said semiconductor of the second conductivity type is a semiconductor substrate of the second conductivity type.

3. The memory bit cell of claim 1 wherein the said semiconductor of the second conductivity type is a well of the second conductivity type disposed in a semiconductor substrate of the first conductivity type.

4. The memory bit cell of claim 1 wherein the first conductivity type is N-type, and the second conductivity type is P-type.

5. The memory bit cell of claim 1 wherein the first conductivity type is P-type, and the second conductivity type is N-type.

6. The memory bit cell of claim 1 wherein one-half of the said diffusions is replaced with shallow trench isolation.

7. The memory bit cell of claim 1 wherein said gate electrode is a polysilicon of the second conductivity type.

8. The memory bit cell of claim 1 wherein said gate electrode is metal used as the gate of MOSFETs of which source and drain diffusions are of the second conductivity type.

9. The memory bit cell of claim 1 wherein said JFET is on when the voltage across the gate-to-source junction of said JFET is 0 volt and said JFET is turned off with a reverse bias voltage applied to the gate-to-source junction.

10. The memory bit cell of claim 1 wherein said JFET is off when the voltage across the gate-to-source junction of said JFET is 0 volt and said JFET is turned on with a forward bias voltage applied to the gate-to-source junction.

11. The memory bit cell of claim 1 wherein pinch-off voltages of said JFET are the same for program mode and read mode.

12. The memory bit cell of claim 1 wherein pinch-off voltages of said JFET differ and are optimized separately for program mode and read mode.

13. The memory bit cell of claim 1 wherein the bit cell is a two-dimensional metal-oxide-semiconductor (MOS) structure.

14. The memory bit cell of claim 1 wherein the bit cell is a three-dimensional MOS structure.

15. The memory bit cell of claim 1 wherein the said semiconductor substrate is a bulk silicon wafer.

16. The memory bit cell of claim 1 wherein the said semiconductor substrate is an epitaxial silicon wafer.
